(19) United States
(12) Patent Application Publication
(10) Pub. No.: US 2009/0006926 A1
(43) Pub. Date: Jan. 1, 2009

(54) Device Providing Selective Error Correction Data Reception

(75) Inventors: Arie Geert Cornelis Koppelaar, Giessen (NL); Onno Eerenberg, Oisterwijk (NL); Armand Michael Stuivenwold, Nijmegen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/097,677

(22) PCT Filed: Dec. 12, 2006
(86) PCT No.: PCT/IB06/54813

§ 371 Date: Jun. 16, 2008

(30) Foreign Application Priority Data
Dec. 16, 2005 (EP) 05112278.6
Dec. 13, 2006 (IB) PCT/IB2006/054813

(51) Int. Cl. H03M 13/17; G06F 11/07

(52) U.S. Cl. 714/762; 714/E11.023

(57) ABSTRACT

In transmission systems using digital video broadcasting standards for handheld terminals data is transmitted in bursts. A decoder unit (25) is provided to correct errors in the data. An error amount determination unit (30) is provided to determine, when the amount of error correction data for error correction is sufficient for a successful error correction. Therefore, in the average, power consumption of the device (1) may be reduced by an early receiver front-end switch-off.

### FIELD OF THE INVENTION

The present invention relates to a device and method for receiving bursts in a communications network. More particularly, the present invention relates to a mobile device, especially a handheld terminal, to receive multimedia services over digital terrestrial broadcasting networks.

### BACKGROUND OF THE INVENTION

State-of-the-art document ETSI EN 302 304 V1.1.1 (2004-11) with the title “Digital Video Broadcasting (DVB); Transmission System for Handheld Terminals (DVB-H)” of the European Broadcasting Union describes the transmission system using digital video broadcasting standards to provide an efficient way of carrying multimedia services over digital terrestrial broadcasting networks to handheld terminals (DVB-H). Thereby, a full DVB-H system is defined by combining elements in the physical and link layers as well as service information. The link layer for DVB-H makes use of time-slicing in order to reduce the average power consumption of the terminal and enabling smooth and seamless frequency handover, and of multiprotocol encapsulation for transmission of IP-based data and Reed-Solomon parities. Forward error correction is applied on a multiprotocol encapsulation and forward error correction (MPE-FEC) frame for an improvement in the carrier to noise performance and Doppler performance in mobile channels, also improving tolerance to impulse interference resulting in a more robust receiver.

The conceptual structure of a DVB-H receiver includes a time-slicing module and an MPE-FEC module. The time-slicing module aims to save receiver power consumption while enabling to perform smooth and seamless frequency handover. The MPE-FEC module offers over the physical layer transmission, a complementary forward error correction allowing the receiver to cope with particularly difficult receiving conditions.

State-of-the-art document GB 2 406 483 A describes a method of transmitting bursts in a terrestrial digital video broadcasting network being used to transmit internet protocol datagrams to receiving devices using multiprotocol encapsulation. Thereby, application data is transmitted in bursts different from bursts for forward error correction data. Further, in order to save power, a controller instructs the receiver to listen for forward error correction data and receives forward error correction data, but if no error is detected in the application data burst, then to listen for application data only and skip the forward error correction data burst.

The method known from GB 2 406 483 A has the disadvantage that reception of the forward error correction data is necessary most of the time, because the multiprotocol encapsulation data is hardly error free.

### OBJECT AND SUMMARY OF THE INVENTION

It is an object of the invention to provide a device and a method for receiving bursts in a communications network with an improved receiving performance, especially with an improved power saving functionality.

This object is solved by a device as defined in claim 1. Advantageous developments of the invention are mentioned in the dependent claims.

The present invention has the further advantage that an early switch-off of the receiving unit may be provided to reduce the average power consumption of the device. This means that a significant power reduction is obtained when receiving a large number of bursts.

According to the measure as defined in claim 2, the application data is stored in an application data table having, for example, 1024 rows and 191 columns, and the error correction data is stored in a Reed-Solomon data table having, for example, 1024 rows and 64 columns. In such a case, error correction is processed individually on each of the rows of the frame comprising both the application data table and the Reed-Solomon data table. That means that the Reed-Solomon decoder processes a row comprising both application data and error correction data. But, the decoder unit may perform the error correction only with a part of the error correction data. The amount of error correction data necessary for a successful decoding depends on the amount of correctly received application data. The decoder unit determines the amount of necessary error correction data on the basis of the data received, wherein this decision is made individually for each frame or each burst.

The measure as defined in claim 3 has the advantage that the computational burden is relatively small. Hence, a fast decision is possible to determine the amount of error correction data necessary for successful error correction. Further, the error amount may be determined in advance before receiving or analyzing individual symbols of the error correction data. Thereby, according to the measure as defined in claim 4, a column of the application data table counts as erroneous when it comprises one or more erroneous symbols.

The measure as defined in claim 5 has the advantage that the error amount is determined row-wise so that the determination of the amount of error correction data necessary for a successful error correction is optimized. Hence, an earlier switch-off of the receiving unit is enabled in the average compared to a column-wise determination of the error amount. In this case, an error or erasure information relating to the individual symbols of the application data table and perhaps the Reed-Solomon data table may be used to determine the number of erroneous symbols of a row of the application data table and perhaps the Reed-Solomon data table. When limiting the determination of the amount of error correction data necessary for a successful error correction to the application data table part of the row of the frame, an error amount determination is possible before reception of the error correction data. But, the symbols of the error correction data stored in the Reed-Solomon data table part of the frame may also be used to determine the error amount of error correction data necessary for a successful error decoding to refine the error amount determination. Therewith, an earlier receiving unit switch-off may be provided, as suggested by the measure as defined in claim 9. But, the measure as defined in claim 8 provides an error amount determination with a reduced computational burden.

According to the measure as defined in claim 10 the timing for an end of reception is optimized.

According to the measures as defined in claim 11 and 12, further parameters may be used to optimize error correction. For example, according to the measure as defined in claim 12, a security distance may be used, to allow error correction, even when some undetected errors are occurring during data processing.

These and other aspects of the invention will be apparent from and elucidated with reference to the embodiments described hereinafter.

### BRIEF DESCRIPTION OF THE DRAWINGS

The present invention will become readily understood from the following description of preferred embodiments thereof made with reference to the accompanying drawings, in which like parts are designated by like reference signs and in which:

FIG. 1 shows a block diagram of a device for receiving bursts according to a preferred embodiment of the present invention;

FIG. 2 illustrates a frame in a memory of a memory unit of the device according to the preferred embodiment of the invention;

FIG. 3 illustrates an error table used by an error amount determination unit of the device according to the preferred embodiment of the invention to determine an error amount with reference to columns of the frame, as shown in FIG. 2; and

FIG. 4 shows an error table used by the error amount determination unit of the device according to the preferred embodiment of the invention with reference to rows of the frame, as shown in FIG. 2.

### DESCRIPTION OF EMBODIMENTS

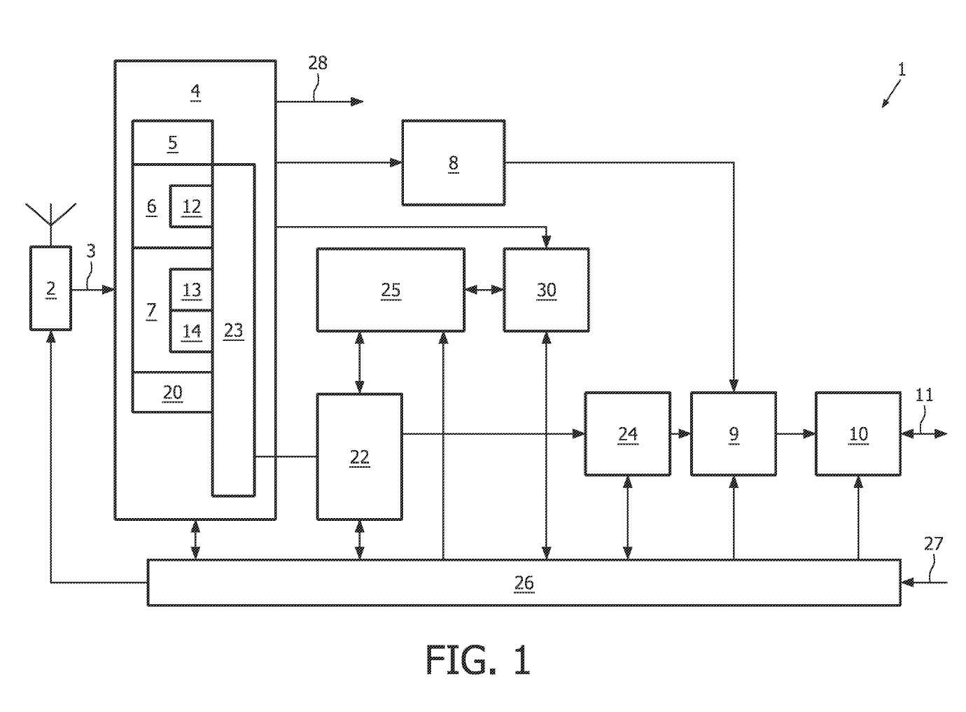

FIG. 1 shows a schematic block diagram of a link-layer of a device 1 for receiving bursts in a communications network. The device 1 can be used in a transmission system using digital video broadcasting standards to provide a way of carrying multimedia services over digital terrestrial broadcasting networks. For example, the device 1 may be a part of a handheld terminal, or a mobile phone or another, especially battery powered, apparatus. But, the device 1 and the method of the invention can also be included in or processed by other equipments.

The device 1 according to the preferred embodiment comprises a receiving unit 2. The receiving unit 2 receives consecutive bursts via the communications network and outputs a transport stream over a channel 3. Thereby, each of the bursts may comprise multiprotocol encapsulation data containing IP-data as possible forward error correction data. Thereby, different bursts may be transmitted over different channels. Timing offset information may be provided to indicate the timing between succeeding bursts. In case of digital video broadcasting for handheld terminals, such a timing offset information is known as “delta-t”.

Further, the device 1 comprises a demultiplexer 4. The demultiplexer 4, is, for example, arranged as a MPEG-2 Transport Stream demultiplexer, wherein the moving picture compression standard MPEG-2 targets studio-quality television and multiple CD-quality audio channels at 4 to 6 Mbps and has also been extended to optimally address high-definition television (HDTV). But, other coding standards, especially for coding of moving pictures and associated audio, may also be provided by the demultiplexer 4. The demultiplexer 4 receives the transport stream over the channel 3. The demultiplexer 4 comprises packet identifier (PID) filters 5, selecting the transport stream packets of an elementary stream. The packet identifier filters 5 are used in combination with service information (SI) and program specific information (PSI) filters 6 and de-encapsulation filters 7 for filtering of service information, program specific information and application information. Selected SI/PSI sections are stored in their corresponding queues 8 and transmitted by a queue manager 9. The selected service information is subjected to several operations before it is transmitted via a serial peripheral interface (SPI) 10 and a channel 11 to an application engine.

Sections filtering of the service information and program specific information filters 6 are accompanied by a cyclic redundancy check (CRC) 12. De-encapsulator filtering by the de-encapsulation filter 6 is accompanied by a cyclic redundancy check 13 as well as a check sum calculation 14. The cyclic redundancy check 12, the cyclic redundancy check 13 and the check sum calculation 14 are sources for error information. A further source for error information is a transport error indicator in a transport stream packet main header. When an error occurs, an error flag generation unit 20 of the demultiplexer 4 generates an erasure flag for the corresponding datagram fragments. Thereby, a datagram is a network layer data frame. In the case of internet protocol, a datagram is an internet protocol datagram. In general, a datagram is a network layer packet with full address information enabling it to be routed to the endpoint without further information. The receiving unit 2 receives bursts comprising sections. Datagrams are encapsulated in sections, and when an error occurs in anyone of those sections, the erasure flag generation unit 20 generates an erasure for the datagram of the erroneous section.

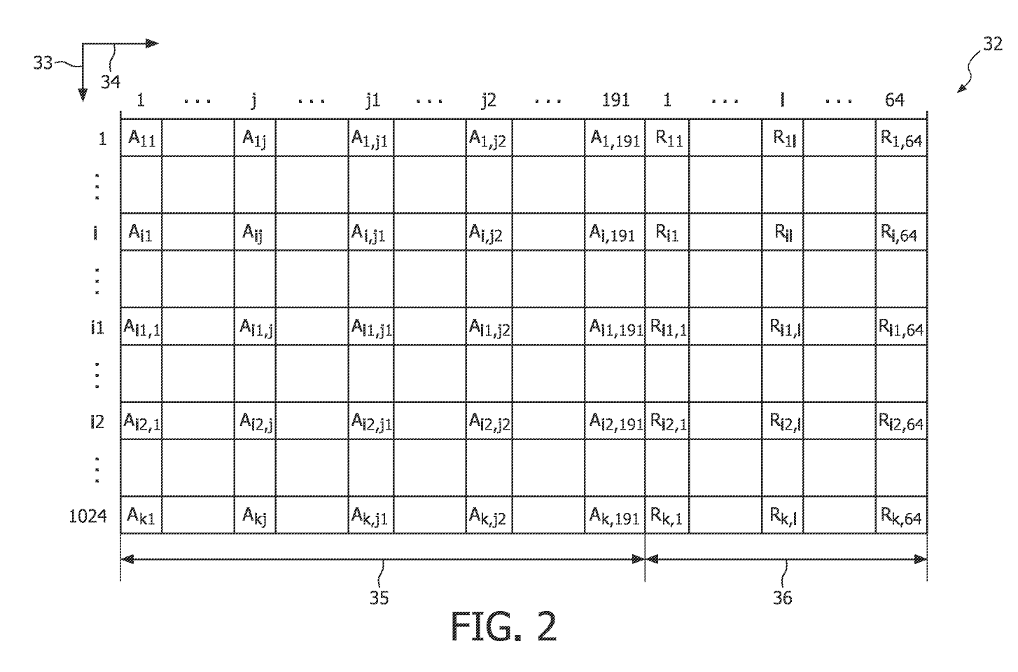

The application data received in the form of datagrams and the error correction data received is sent from the demultiplexer 4 to a memory unit 22. The memory unit 22 comprises a memory, and a frame in that memory is arranged to store the datagrams received, as described in detail with reference to FIG. 2.

The device 1 comprises an internet protocol readout unit 24 and a decoder unit 25. The decoder unit 25 is adapted to perform a forward error correction on the data stored in the frame of the memory unit 22. After forward error correction processing, the multiprotocol encapsulation data is sent to the queue manager 9 via the internet protocol readout unit 24. The internet protocol readout unit 24 identifies datagrams in the MPE-FEC memory of the memory unit 22. Therefore, it analyses a header information of each of the datagrams and reads its length information. A control and power saving unit 26 is connected with the demultiplexer 4, the memory unit 22, the decoder unit 25, the internet protocol readout unit 24, the queue manager 9 and the SPI 10 for control and power saving operation. Further, the control and power saving unit 26 is connected with the receiving unit 2 to switch off the receiving unit 2 between the bursts received and, perhaps, before the end of an individual burst. The control and power saving unit 26 receives data from an interchip communication channel (I2C) 27. The control and power saving unit 26 receives internet protocol entry data from the entry table generation unit 21 and sends those data to the internet protocol readout unit for internet protocol readout. Further, the demultiplexer 4 may have one or more outputs, for example an output 28 for a partial or full transport stream for other services, such as terrestrial digital video broadcasting.

Further, the device 1 comprises an error amount determination unit 30. The error amount determination unit 30 determines an error amount of erroneous application data received, and, may further determine an error amount of error correction data, especially Reed-Solomon parities, received. Thereby, the error amount determination unit 30 determines the error amount with reference to the positions of the symbols of the datagrams in the frame of the memory of the memory unit 22, as described in further detail with reference to FIG. 2. Further, the error amount determination unit 30 determines an amount of error correction data that is necessary for the decoder unit 25 to successfully perform an error correction on the data stored in the frame of the memory unit 22. Also, the error amount determination unit 30 determines the amount of correctly received error correction data and compares the amount of correctly received error correction data with the amount of error correction data necessary for error correction processing. In case that the amount of correctly received error correction data is sufficient for error correction processing, the error amount determination 30 sends a request to the control and power saving unit 26 to request an end of reception of error correction data. Then, the control and power saving unit 26 instructs the receiving unit 2 to end reception of error correction data. Therefore, a part of the error correction data may not be received and a part of the frame of the memory unit 22 may not be filled with Reed-Solomon parities.

FIG. 2 shows a preferred embodiment of the frame 32 in the memory of the memory unit 22. In this embodiment, the frame 32 is arranged as a multiprotocol encapsulation and forward error correction frame 32. The frame 32 is a table of symbols Aᵢⱼ and Rᵢₗ, wherein i is greater or equal than 1 and lower or equal than k, j is greater or equal than 1 and lower or equal than 191, and 1 is greater or equal than 1 and lower or equal than 64. Thereby, k is the number of rows of the frame 32 counted in a direction 33 from 1 to, for example, 1024. The number of columns of the frame 32 is 191+64=255. The frame 32 comprises an application data table 35 and an error correction data table 36, wherein the error correction data table 36 of the preferred embodiment is a Reed-Solomon data table 36. The columns in the application data table 35 part of the frame 32 are counted in a direction 34, and the columns in the Reed-Solomon data table 36 part of the frame 32 are also counted in the direction 34. The application data table 35 is filled with the datagrams received by the memory unit 22 so that the application data table 35 is filled with application data and, perhaps, padding bytes. Hence, at the position of the symbols Aᵢⱼ application data or padding data is stored. The Reed-Solomon parities are stored in the Reed-Solomon data table 36, as shown by the symbols Rᵢₗ.

The number k of rows in the frame 32 is signaled in a descriptor of the received stream. All multiprotocol encapsulation sections and multiprotocol encapsulation forward error correction sections are protected by a CRC-32 code, which reliably detect all erroneous sections. For every correctly received section belonging to the application data table 35 or to the Reed-Solomon data table 36, the start address of the payload within the section is determined from the section header to put the payload in the right position of the respective table 35 or 36. But, some sections or fragments of sections may be lost during transmission so that a number of holes may remain in the application data table 35 and/or the Reed-Solomon data table 36. All correctly received bytes and application data padding, shown by the symbols Aᵢⱼ, are then regarded as reliable and all byte positions in the holes are marked as unreliable. Further, punctured columns of the Reed-Solomon data table 36 are also marked as unreliable for Reed-Solomon decoding. Hence, each symbol Aᵢⱼ and Rᵢₗ is marked as either reliable or unreliable. It should be noted that this error information is an erasure information, because the position, i.e. the position of the symbol Aᵢⱼ or Rᵢₗ, of the error is known. The decoder unit 25 may then correct up to 64 symbols Aᵢⱼ or Rᵢₗ in each row i, that means for each 255-Byte codeword.

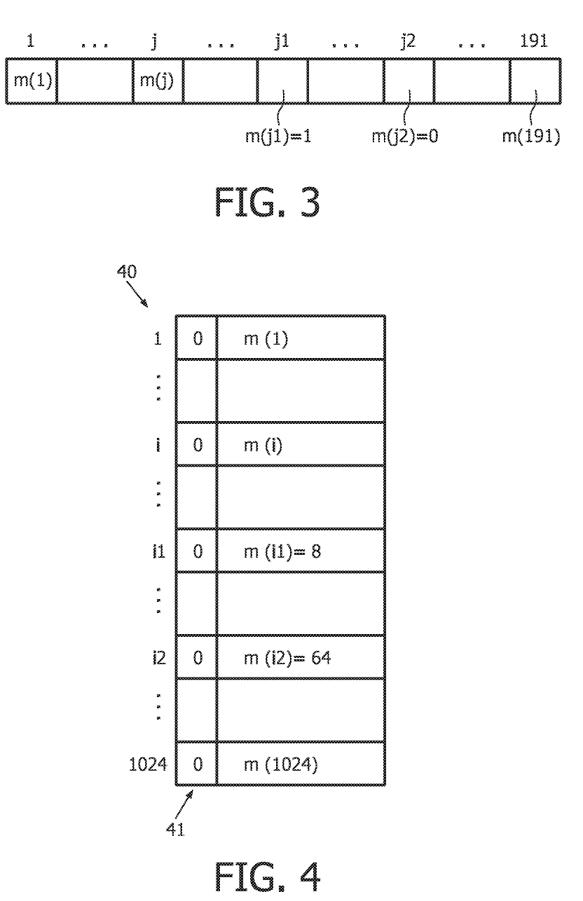

The error amount determination unit 30 provides two different methods to determine an error amount of erroneous application data received. A first method to determine the error amount of erroneous application data received is described in further detail with reference to FIGS. 2 and 3. A second method is described in further detail with reference to FIGS. 2 and 4.

FIG. 3 shows a 191-Bit field used by the error amount determination unit 30 to determine an error amount of erroneous application data received on the basis of erroneous columns of the frame 32. Therefore, a column j of the application data table 35 is determined as erroneous when at least a symbol Aᵢⱼ is erroneous, as known from the erasure information. If column j is erroneous then an error flag is raised. For example, as shown in FIG. 3, the column j1 comprises at least an erroneous symbol Aᵢⱼ₁ so that m(j1) is set to 1. Column j2 comprises no erroneous symbol Aᵢⱼ₂ so that m(j2) is set to 0. After reception of the application data all values m(j) are set either to 0 or to 1.

Then, the error amount determination unit 30 calculates the sum of all m(j) for 1≦j≦191. The result is the number of erroneous columns. Hence, with this first method the error amount determination unit 30 determines the error amount of erroneous columns as the number of columns j, each comprising at least an erroneous symbol Aᵢⱼ.

The sum of m(j) determined equals the amount of error correction data that is necessary for the decoder unit 25 to perform a successful error correction. In case of RS [255, 191, 64], wherein 255 is the number of columns of the frame 32, 191 is the number of application data columns and 64 is the number of Reed-Solomon data table columns, the sum of all m(j) must be lower than 65.

The error amount determination unit 30 determines, whether columns 1 of the Reed-Solomon data table 36 are erroneous or not, while the associated stream is received by the receiving unit 2. When the number of correctly received columns 1 of the Reed-Solomon data table 36 is greater or equal to the sum of m(j) for j greater or equal to 1 and lower or equal to 191, then the error amount determination unit 30 determines that the amount of correctly received Reed-Solomon parities is not less than the amount of Reed-Solomon parities necessary to perform the error correction. Hence, the error amount determination unit 30 sends the result of this decision to the control and power saving unit 26. The control and power saving unit 26 then requests an early receiving unit 2 front-end switch-off. The not received columns with Reed-Solomon parities are designated as erasures.

The error amount determination unit 30 may send the signal to the control and power saving unit 26 when the number of correctly received columns of the Reed-Solomon data table 36 is equal to the sum of all m(j). But, a safety distance may be provided. In case of such a safety distance, the error amount determination unit 30 determines when the number of correctly received columns of the Reed-Solomon data table 36 is equal to the sum of all m(j1) plus a safety distance. Hence, a few more columns of Reed-Solomon data are received as necessary by the decision based on the m(j)-values. Hence, the duration of reception is increased in accordance with the amount of the safety distance. Then, the decoder unit 25 may perform a successful error correction, even when undetected errors are hidden in the application data table 35 or the error correction data table 36 of the frame 32.

FIG. 4 shows a table 40 used by the error amount determination unit 30 to determine an error amount on the basis of a row-wise decision. Therefore, the error amount determination unit 30 determines for each row i of the frame 32 the number of erroneous symbols Aᵢⱼ and, probably, Rᵢₗ. This determination may be made with regard to the application data table 35 part of the row i or to both the application data table 35 part and the error correction data table 36 part of the row i, while the Reed-Solomon parities are received.

First, determination of the error amount with respect to the whole row, as already received, is described. While the symbols Aᵢⱼ and Rᵢₗ are stored at their corresponding position in the frame 32, the error amount determination unit 30 determines the number m(i) of erasures for each row i. Thereby, unfilled positions in the frame 32, i.e. holes in the frame 32 due to missing data or not yet received symbols Aᵢⱼ, Rᵢₗ count as one error per missing symbol Aᵢⱼ or Rᵢₗ. After storing the application data in the application data table 35, Reed-Solomon parities may be necessary. And, Reed-Solomon parities Rᵢₗ are stored at their corresponding position in the Reed-Solomon data table 36 during reception. As shown in FIG. 4, the number m(i1) of erasures in row i1 is equal to 8 and therefore smaller than 64. Further, the number m(i2) of erasures in row i2 is 64 at this moment. The error amount determination unit 30 determines the maximum number m(i) of erasures with respect to all rows i. Assume that all other rows i with i not equal to i1 or i2 have a number m(i) of erasures that is less than 64. Then, the error amount determination unit 30 determines a remaining error amount to 64. The error amount is thereby determined as the sum of erasures in the application data table 35 and the number of erasures in the Reed-Solomon data table 36. The number m(i2) of erasures in row i2 is 64, so that the amount of Reed-Solomon parities associated to row i2 is now sufficient to allow a successful error correction. Row i2 was assumed as the row with the most remaining erasures so that a successful error correction is now possible for the frame 32, even when some columns of Reed-Solomon parities in the Reed-Solomon data table 36 have not been received. Nevertheless, the error amount determination unit 30 sends a signal to the control and power saving unit 26 that the amount of error correction data that is necessary for the decoder unit 25 to perform an error correction is now equal to the amount of error correction data necessary to perform the error correction. As a result, the control and power saving unit 26 requests an early receiving unit 2 front-end switch-off.

Optionally, the number of correctly received symbols is counted. If all rows i have 191 or more correctly received symbols Aᵢⱼ and Rᵢₗ, then the received Reed-Solomon parities are sufficient and the remaining Reed-Solomon data is not needed anymore in order to reconstruct the frame 32.

It should be noted that a safety distance may be provided. In such a case, the maximum number of erasures for each of the rows i is set to a value below the maximum error correction capability of the decoder unit 25, for example to a value that is lower than 64.

It should be noted that the computational burden may be reduced by an error indicator field 41 of the table 40. Thereby, a bit is associated to each number m(i) of erasures in row i. When the number m(i) of erasures in row i is smaller or equal to the error correction capability of the decoder unit 25, this flag is set to 0. Therefore, the error amount determination unit 30 may count the raised flags in the error indicator field 41 to determine, whether the amount of Reed-Solomon parities received is sufficient for error correction. The amount of error correction data received is sufficient, when all bits in the error indicator field 41 are set to “0”. An advantage is that the error amount determination unit 30 may only monitor rows i having a number m(i) of erasures that is greater than the error correction capability of the decoder unit 25.

The error amount determination unit 30 may also determine the error amount only with respect to the symbols Aᵢⱼ of the application data table 35. In such a case, after reception of the application data 35, the number m(i) of erasures limited to the application data table 35 part of each row i is determined. The maximum of the numbers m(i) for all rows i is then used to determine the error amount of erroneous application data received. Then, this maximum is used to determine the amount of error correction data that is necessary for the decoder unit 25 to perform the error correction. The error amount determination unit 30 determines the amount of correctly received error correction data as the number of correctly received columns 1 of Reed-Solomon data. When the number of correctly received columns 1 of Reed-Solomon parities is equal to or greater than the maximum of the numbers m(i), then the error amount determination unit 30 sends a signal to the control and power saving unit 26 to request an end of reception of Reed-Solomon parities. Then, the control and power saving unit 26 controls the receiving unit 2 to perform an early receiving unit 2 front-end switch-off.

It should be noted that the number m(i) of erasures in a row i is an example for a row error number determined with respect to a row i. Further, the maximum number m(i) of erasures with respect to all rows i is an example for a maximum row error number.

Although exemplary embodiments of the invention have been disclosed, it will be apparent to those skilled in the art that various changes and modifications can be made which will achieve some of the advantages of the invention without departing from the spirit and scope of the invention. Such modifications to the inventive concept are intended to be covered by the appended claims in which the reference signs shall not be construed as limiting the scope of the invention. Further, in the description and the appended claims the meaning of “comprising” is not to be understood as excluding other elements or steps. Further, “a” or “an” does not exclude a plurality, and a single processor or other unit may fulfill the functions of several means recited in the claims.

1. Device for receiving bursts in a communications network, especially mobile device, which device comprises a receiving unit, a memory unit, a decoder unit and an error amount determination unit, wherein said receiving unit is adapted to receive said bursts comprising application data and error correction data and to send at least a part of said application data and at least a part of said error correction data to said memory unit, wherein said memory unit is adapted to store said application and error correction data received from said receiving unit in a frame of a memory of said memory unit, wherein said decoder unit is adapted to perform an error correction on said data stored in said frame of said memory of said memory unit, wherein said error amount determination unit is adapted to determine an error amount of erroneous application data received, to determine an amount of error correction data that is necessary for said decoder unit to perform said error correction, to determine an amount of correctly received error correction data, and to request an end of reception of error correction data, when said amount of correctly received error correction data is not less than said amount of said error correction data necessary to perform said error correction.

2. Device according to claim 1, characterized in that said frame is a multiprotocol encapsulation and forward error correction frame, that said frame comprises an application data table and a Reed-Solomon data table, that said application data is stored in said application data table of said frame and that said error correction data is stored in said Reed-Solomon data table of said frame, and that said decoder unit is a Reed-Solomon decoder unit.

3. Device according to claim 1, characterized in that said error amount determination unit is adapted to determine said error amount of erroneous application data as a number of erroneous columns of an application data table of said frame.

4. Device according to claim 3, characterized in that a column of said application data table is determined as erroneous when it comprises at least an erroneous symbol.

5. Device according to claim 1, characterized in that said error amount determination unit is adapted to determine said error amount of erroneous application data on the basis of row error numbers, wherein each row error number is determined with respect to a row of an application data table of said frame.

6. Device according to claim 5, characterized in that said error amount determination unit is adapted to determine said error amount of erroneous application data as a maximum row error number of said row error numbers, wherein each of said row error numbers is determined as a number of erroneous symbols in said row of said application data table of said frame.

7. Device according to claim 2, characterized in that said error amount determination unit is adapted to determine said amount of error correction data that is necessary for error correction as a number of columns of a Reed-Solomon data table of said frame.

8. Device according to claim 7, characterized in that said error amount determination unit is adapted to request an end of reception of error correction data, when a number of correctly received columns of said Reed-Solomon data table equals said number of columns determined as said error amount.

9. Device according to claim 1, characterized in that said error amount determination unit is adapted to determine said amount of error correction data that is necessary for error correction, while said error correction data is stored in said frame.

10. Device according to claim 1, characterized in that said error amount determination unit is adapted to request an end of reception of error correction data, when said error amount determination unit determines that for each row of said frame a remaining error amount is within an error correction capability of said decoder unit.

11. Device according to claim 10, characterized in that said error amount determination unit is adapted to request an end of reception of error correction data when for each row of said frame, a number of correct symbols of said row is not less than a number of columns of an application data table of said frame.

12. Device according to claim 1, characterized in that said error amount determination unit is adapted to request an end of reception of error correction data when for each row of said frame, a number of correct symbols of said row is not less than a sum of a number of columns of an application data table of said frame and a security distance.
